(19) United States
(12) Patent Application Publication
(10) Pub. No.: US 2026/0255636 A1
(43) Pub. Date: Aug. 27, 2026

(54) TRANSISTOR

(71) Applicant: Innolux Corporation, Miaoli County (TW)

(72) Inventors: Yeong-E Chen, Miaoli County (TW); Yu-Mei Chiu, Miaoli County (TW)

(73) Assignee: Innolux Corporation, Miaoli County (TW)

(21) Appl. No.: 19/449,414

(22) Filed: Jan. 15, 2026

(30) Foreign Application Priority Data
Feb. 24, 2025 (CN) 202510204841.2

(51) Int. Cl. H10D 30/67; H10D 86/40

(52) U.S. Cl. CPC H10D 30/6757; H10D 30/6717; H10D 30/6731; H10D 86/421

(57) ABSTRACT

The present disclosure provides a transistor including a semiconductor and a plurality of gate electrodes overlapping with the semiconductor. The semiconductor includes a plurality of channel regions, at least one of middle regions, a first and a second regions, and a first lightly doped region. Each of the channel regions overlaps with one of the gate electrodes. One of the at least one of middle regions is disposed between the neighboring two of the channel regions. The first and the second regions are located at opposite two ends of the semiconductor. The first lightly doped region is disposed between the first region and one of the channel regions adjacent to the first region.

### CROSS-REFERENCE TO RELATED APPLICATION

This application claims the priority benefit of China application serial no. 202510204841.2, filed on February 24, 2025. The entirety of each of the above-mentioned patent applications is hereby incorporated by reference herein and made a part of this specification.

### BACKGROUND

### Technical Field

The present disclosure relates to a semiconductor component, and particularly relates to a transistor.

### Description of Related Art

Low-temperature polycrystalline silicon (LTPS) thin-film transistors (TFTs) can be used as switching elements in electronic devices. For example, the LTPS-TFTs are commonly found in liquid crystal displays (LCDs), organic light emitting diode (OLEDs) and other display techniques, and are widely used especially for the devices such as high-resolution displays, smartphones, tablets.

However, the LTPS-TFTs have relatively lower electron mobility as compared to metal oxide semiconductor field effect transistors (MOSFETs), and thus need to operate under relatively higher voltage. This means that the LTPS-TFTs have a larger electric field at the drain and is easily affected by the hot carrier effect, or need to consider the generation of the undesired kink current and/or the generation of leakage current (Ioff) in the non-operating state.

As the electronic devices continue to be developed towards lighter, thinner, shorter, and smaller aspects and the user’s requirements for the performance of the electronic devices continue to increase, the existing LTPS-TFTs may be hard to meet the current or future requirements for the reliability or quality of the electronic devices.

### SUMMARY

The present disclosure provides a transistor in which a first lightly doped region is disposed between a first region and one of a plurality of channel regions, so as to reduce the influences cause by the hot carrier effect and/or by the leakage current, and/or to decrease the phenomenon of generating kink current at the desired operating voltage.

According to an embodiment of the present disclosure, the transistor includes a semiconductor and a plurality of gates overlapping with the semiconductor. The semiconductor includes a plurality of channel regions, at least one middle region, a first region, a second region, and a first lightly doped region. Each of the channel regions overlaps with one of the gates. One of the at least one middle region is disposed between neighboring two of the channel regions. The first region and the second region are respectively located at opposite ends of the semiconductor. The first lightly doped region is disposed between the first region and one of the channel regions adjacent to the first region.

Based on the above, in the transistor of the embodiment of the present disclosure, the first lightly doped region is disposed between the first region (e.g., the drain region) and one of the channel regions, so that the electric field on the drain end can be reduced, and thereby improving the influence caused by the hot carrier effect, reducing the phenomenon of generating kink current at the desired operating voltage, and/or decreasing the leakage current generated in the non-operating state.

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of an electronic device according to an embodiment of the present disclosure.

FIG. 2A is a schematic top view of a transistor according to a first embodiment of the present disclosure.

FIG. 2B is a schematic top view of a transistor according to a second embodiment of the present disclosure.

FIG. 2C is a schematic top view of a transistor according to a third embodiment of the present disclosure.

FIG. 3 is a schematic top view of a transistor according to a fourth embodiment of the present disclosure.

FIG. 4A is a schematic top view of a transistor according to a fifth embodiment of the present disclosure, and FIG. 4B is a schematic cross-sectional view taken along line A-A in FIG. 4A.

FIG. 5A is a schematic top view of a transistor according to a sixth embodiment of the present disclosure.

FIG. 5B is a schematic top view of a transistor according to a seventh embodiment of the present disclosure.

FIG. 6 is a schematic view showing a relationship of the current and the voltage of a transistor according to an embodiment of the present disclosure.

### DESCRIPTION OF THE EMBODIMENTS

In the embodiments provided later, the same or similar reference numerals are used to refer to the same or similar elements, and the descriptions will not be repeated. In addition, as long as the features of the various embodiments do not depart from or conflict with the spirit of the disclosure, the embodiments may be mixed and matched as desired. It is intended that the disclosure covers modifications and variations provided that they fall within the scope of the following claims and their equivalents. That is, in the following embodiments, technical features in several different embodiments may be replaced, reorganized, and mixed to complete other embodiments without departing from the spirit of the disclosure. Moreover, the terms such as “first” and “second” mentioned in the specification or the claims are only used to name different elements or to distinguish different embodiments or scopes, and are not intended to limit the upper or lower limit of the number of the elements, nor are they intended to limit the manufacturing order or disposition order of the elements.

In the text, the terms “about,” “approximately,” “essentially,” or “substantially” usually implies that a value is within 10% of a given value or range, or within 5%, 3%, 2%, 1%, or 0.5% of a given value or range. In addition, the description “a given range from a first value to a second value” or “a given range between a first value and a second value” implies that the given range includes the first value, the second value, and other values in between. In some embodiments of this disclosure, the thickness, length, and width may be obtained through a measurement using an optical microscope (OM). The thickness or the width may be obtained by measuring from a cross-sectional image in an electron microscope, but is not limited thereto.

The electronic device of this disclosure may be applied to a power module, a semiconductor package device, a display device, a light-emitting device, a back-light device, an antenna device (e.g., a liquid crystal antenna), a sensing device, a testing device or a tiled device, but is not limited thereto. The electronic device includes a rollable electronic device or a flexible electronic device. The display device may include, for example, a non-self-luminous panel such as a liquid crystal panel or other self-luminous panels, but is not limited thereto. The antenna device may be a liquid crystal type antenna device or a non-liquid crystal type antenna device, but is not limited thereto. The sensing device may be a sensing device for sensing capacitance, light, heat or ultrasound, but is not limited thereto. The electronic device may include an electronic unit including a passive component and an active component, such as a capacitor, a resistor, an inductor, a diode, and a transistor. The diode may include a light emitting diode or a photodiode. The light emitting diode may include, for example, an organic light emitting diode (OLED), a mini-LED, a micro-LED, or a quantum dot light emitting diode (QLED, QDLED), but is not limited thereto. The tiled device may be, for example, a display tiled device or an antenna tiled device, but is not limited thereto. It should be understood that the electronic device may be any combination of the aforementioned arrangements, but is not limited thereto.

The exemplary embodiments of this disclosure are described in the following for example, and the same reference numerals used in the figures and descriptions are represented to the same or similar portions.

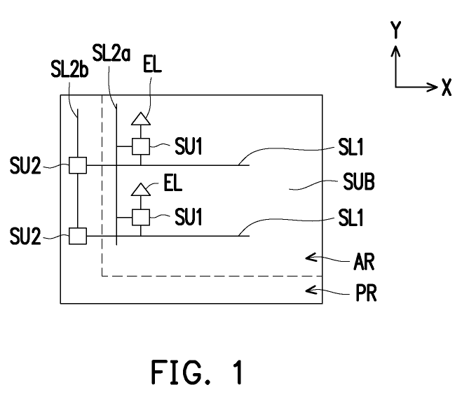

Referring to FIG. 1, an electronic device 100 may include a substrate SUB, electronic components EL, switching units SU1, SU2, and signal lines SL1, SL2a, SL2b.

The substrate SUB may include an active region AR and a peripheral region PR. In some embodiments, the material of the substrate SUB may include a glass, a semiconductor material, a quartz, a sapphire, a polyimide (PI), a polycarbonate (PC), a polyethylene terephthalate (PET), other suitable materials, or combinations thereof, but is not limited thereto. According to some embodiments, the semiconductor material may include silicon (Si), germanium (Ge), other suitable semiconductor materials, or combinations thereof.

The electronic components EL may be disposed on the active region AR of the substrate SUB. In some embodiments, the electronic components EL may include electrical chips (e.g., a known good die, KGD), diodes, antenna units, sensors, structures or components formed through semiconductor-related processes, or structures or components formed on the substrate SUB through semiconductor-related processes. In some embodiments, the electronic components EL may include light-emitting components. The light-emitting components may include a light emitting diode (LED), a quantum dot (QD), a fluorescence, a phosphor, other suitable materials, or combinations thereof, but are not limited thereto.

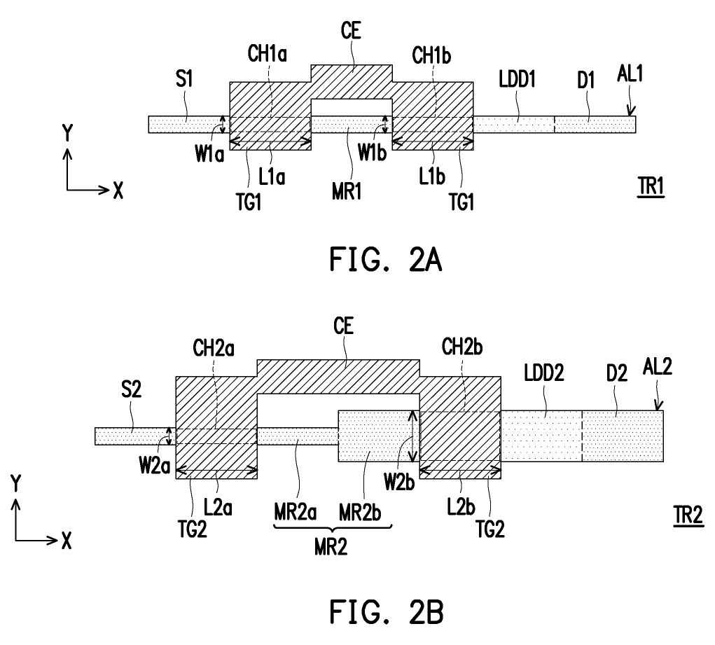

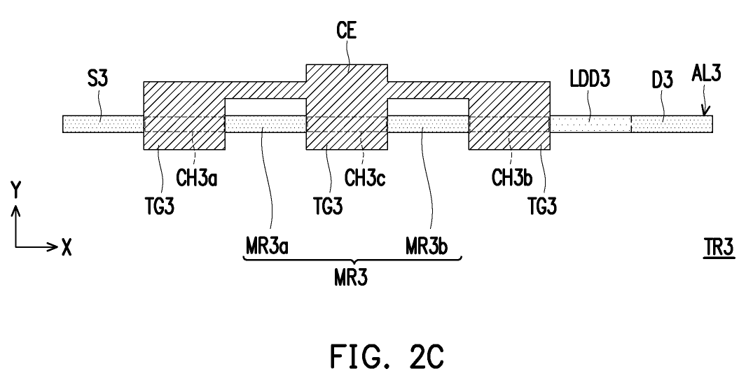

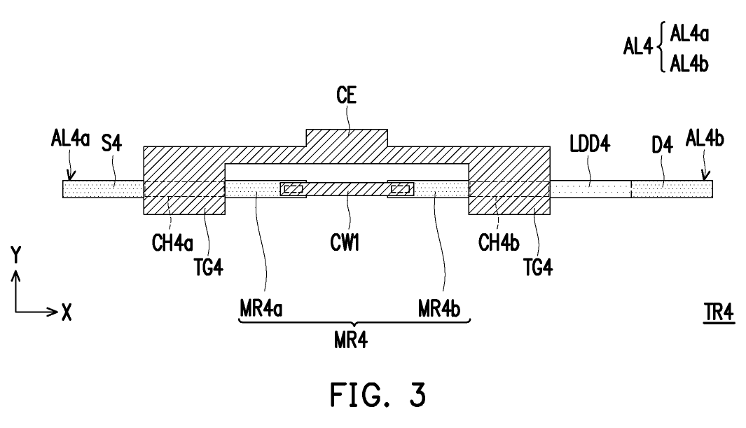

The switching units SU1 may be disposed on the active region AR of the substrate SUB and electrically connected to the electronic components EL. In some embodiments, the switching units SU1 may include transistors (e.g., transistors TR1-TR7 shown in FIG. 2A to FIG. 5B). In some embodiments, the switching units SU1 are electrically connected to the signal line SL1 and the signal line SL2a. In some embodiments, the signal line SL1 may be a conductive wire extending in a horizontal direction (i.e., X direction). In some embodiments, the signal line SL2a may be a conductive wire extending in a vertical direction (i.e., Y direction). The conductive wire may include any suitable conductive material, such as copper (Cu), aluminum (Al), nickel (Ni), molybdenum (Mo), titanium (Ti), alloys or combinations of the above materials, or other suitable materials, but is not limited thereto.

The switching units SU2 may be disposed on the peripheral region PR of the substrate SUB and electrically connected to the signal line SL1 and the signal line SL2b. In some embodiments, the switching units SU2 may include transistors (e.g., TR1-TR7 shown in FIG. 2A to FIG. 5B). In some embodiments, the switching units SU2 may be connected to the switching units SU1 through the signal lines SL1. In some embodiments, the signal line SL2b may be a conductive wire extending in the Y direction. The material of the conductive wire may be the conductive materials as mentioned above, and is not be repeated herein. In some embodiments, the signal line SL2a may be a conductive wire extending on the active region AR of the substrate SUB, while the signal line SL2b may be a conductive wire extending on the peripheral region PR of the substrate SUB.

The following will explain the transistor architecture that may be applicable to at least one of the switching unit SU1 and the switching unit SU2 through FIG. 2A to FIG. 5B. In transistors TR1-TR7, the same or similar components are represented by the same or similar reference numerals, and the descriptions thereof will not be repeated.

In the first embodiment, as shown in FIG. 2A, the transistor TR1 may include a semiconductor AL1 and a plurality of gates TG1 overlapping with the semiconductor AL1. The semiconductor AL1 may include a plurality of channel regions (e.g., a channel region CH1a and a channel region CH1b), at least one middle region MR1, a first region D1 and a second region S1 respectively located at opposite ends of the semiconductor AL1, and a first lightly doped region LDD1 disposed between the first region D1 and the channel region CH1b that is adjacent to the first region D1 among the plurality of channel regions CH1a, CH1b. One of the at least one middle region MR1 is disposed between the channel region CH1a and the channel region CH1b adjacent to each other, so that the electric field at the drain end of the transistor TR1 can be reduced by the first lightly doped region LDD1, and thereby improving the influence caused by the hot carrier effect, reducing the phenomenon of generating kink current at the desired operating voltage, and/or decreasing the leakage current generated in the non-operating state.

In some embodiments, the semiconductor AL1 may include suitable semiconductor materials such as single crystal silicon or polysilicon. In this embodiment, the semiconductor AL1 may include a low temperature polysilicon (LTPS). The gates TG1 may include any suitable conductive material. For example, the gates TG1 may include copper, aluminum, molybdenum, tungsten, gold, chromium, nickel, platinum, titanium, iridium, rhodium, alloys thereof, combinations thereof, or other metal materials with good conductivity, but are not limited thereto. Each of the plurality of channel regions CH1a, CH1b overlaps with one of the plurality of gates TG1. In some embodiments, the plurality of gates TG1 may overlap with the corresponding channel regions CH1a, CH1b. In some embodiments, the plurality of gates TG1 may be electrically connected to each other through the conductor CE. In some embodiments, the conductor CE may be formed simultaneously with the gates TG1 in the same conductive layer during the same process, but is not limited thereto. In some other embodiments, the conductor CE and the gates TG1 may be formed in different conductive layers during different processes. For example, the conductor CE may be one or more of the plurality of wiring layers formed above the gates TG1, but is not limited thereto. In some embodiments, the transistor TR1 may be a top-gate type thin film transistor, but is not limited thereto.

In this embodiment, the first lightly doped region LDD1 of the transistor TR1 may be formed in the semiconductor AL1 in an asymmetric manner. For example, in the case where the first region D1 is a drain region and the second region S1 is a source region, the first lightly doped region LDD1 may be disposed between the channel region CH1b and the first region D1, while the second region S1 directly adjoins the channel region CH1a. As a result, it is beneficial for reducing the component area in such configuration. In this embodiment, the channel region CH1b is adjacent to the first region D1, that is, there are no other channel regions existing between the channel region CH1b and the first region D1.

In this embodiment, the middle region MR1 of the transistor TR1 is between and directly adjacent to the two neighboring channel regions CH1a, CH1b. For example, no lightly doped region is formed in the portion of the middle region MR1 adjacent to the channel regions CH1a, CH1b. As a result, the transistor TR1 is capable of reducing the electric field at the drain end in the case where the impact on the electron mobility is minimized. Accordingly, under the same or smaller component area, the influence caused by the hot carrier effect can be improved, the phenomenon of generating kink current at the desired operating voltage can be reduced, and/or the leakage current generated in the non-operating state can be decreased. In some embodiments, in the case where no lightly doped region is formed in the portion of the middle region MR1 adjacent to the channel regions CH1a, CH1b, the ion concentrations of ions doped in the middle region MR1 would be relatively close. For example, if the ion concentration at any one point in the middle region MR1 is a first concentration, and the ion concentration at any other point is a second concentration, the ratio of the second concentration to the first concentration is less than or equal to 2 when the second concentration is greater than the first concentration. One of the first concentration and the second concentration is the ion concentration at a location in the middle region MR1 adjacent to the channel region CH1a or adjacent to the channel region CH1b.

In some embodiments, the channel region CH1a, the channel region CH1b, the middle region MR1, and the first lightly doped region LDD1 may be regions in the semiconductor AL1 doped with ions. In some embodiments, the channel regions CH1a, CH1b, the middle region MR1, and the first lightly doped region LDD1 may be doped with ions of the same conductivity type (e.g., dopants of the same conductivity type doped in the semiconductor AL1). In some embodiments, the ion concentration of ions doped in the at least one middle region MR1 is greater than the ion concentration of ions doped in the first lightly doped region LDD1. In some embodiments, the ratio of the ion concentration doped in the at least one middle region MR1 to the ion concentration doped in the first lightly doped region LDD1 is greater than or equal to 2. In another embodiment, the ratio of the ion concentration doped in the at least one middle region MR1 to the ion concentration doped in the first lightly doped region LDD1 is greater than or equal to 10.

In some embodiments, as shown in FIG. 2A, the channel length of at least two of the plurality of channel regions (e.g., channel region CH1a and channel region CH1b) may be the same. The channel length may refer to the length of the channel in the direction (i.e., X direction) from the source to the drain. For example, the channel length L1a of the channel region CH1a and the channel length L1b of the channel region CH1b may be the lengths of the channel region CH1a and the channel region CH1b in the X direction. In this embodiment, the channel length L1a of the channel region CH1a may be identical to the channel length L1b of the channel region CH1b, but is not limited thereto. In some other embodiments, the channel lengths of the at least two of the plurality of channel regions (e.g., channel region CH1a and channel region CH1b) may be different.

In some embodiments, as shown in FIG. 2A, the channel width of the at least two of the plurality of channel regions may be the same. The channel width may refer to the width in the direction (i.e., Y direction) perpendicular to the direction from the source to the drain. For example, the channel width W1a of the channel region CH1a and the channel width W1b of the channel region CH1b may be the widths of the channel region CH1a and the channel region CH1b in the Y direction. In this embodiment, the channel width W1a of the channel region CH1a is identical to the channel width W1b of the channel region CH1b, but is not limited thereto. In some other embodiments, the channel widths of the at least two of the plurality of channel regions (e.g., channel region CH1a and channel region CH1b) may be different.

In the second embodiment, as shown in FIG. 2B, the transistor TR2 may similar to the transistor TR1 in the first embodiment. The main difference between the transistor TR2 and the transistor TR1 is that at least two of channel regions have different channel widths. Specifically, the channel width W2b of the channel region CH2b is greater than the channel width W2a of the channel region CH2a. Correspondingly, the middle region MR2 includes a first portion MR2a and a second portion MR2b having different widths. Other components and their material compositions may be referred to the description in the first embodiment and are not repeated herein for brevity. For example, the descriptions of the semiconductor AL2, the channel lengths L1a and L2b of the channel regions CH2a and CH2b, the first region D2, the second region S2, the gates TG2, and the first lightly doped region LDD2 may be referred to the same of similar terms or reference numerals in the first embodiment.

In the third embodiment, as shown in FIG. 2C, the transistor TR3 may not limited to two channel regions. As depicted, the transistor TR3 includes three channel regions CH3a, CH3b, and CH3c. The middle regions MR3a and MR3b are disposed between adjacent channel regions, respectively. The middle regions MR3a and MR3b may have the same width in the Y direction. Apart from the number of channel regions, the remaining structure and components are analogous to those in the first embodiment and thus will not be described again. For example, the descriptions of the semiconductor AL3, the first region D3, the second region S3, the gates TG3, and the first lightly doped region LDD3 may be referred to the same of similar terms or reference numerals described in the first embodiment.

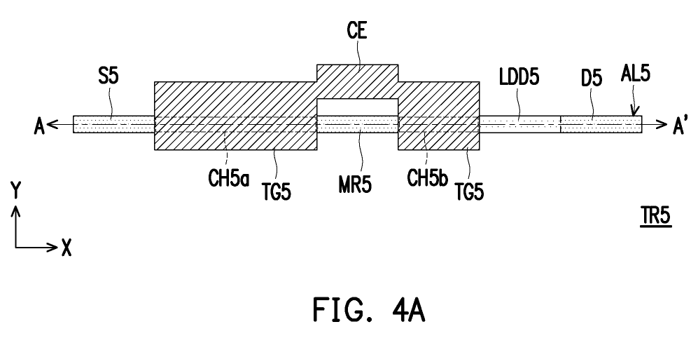

In the fourth embodiment, as shown in FIG. 3, the transistor TR4 may include a semiconductor AL4 including a first active layer AL4a and a second active layer AL4b spaced apart from the first active layer AL4a. The source region S4, the channel region CH4a, and the first portion MR4a of the middle region MR4 are disposed in the first active layer AL4a, while the drain region D4, the first lightly doped region LDD4, the channel region CH4b, and the second portion MR4b of the middle region MR4 are disposed in the second active layer AL4b. Furthermore, a conductor CW1 is provided to electrically connect the first portion MR4a and the second portion MR4b, thereby connecting the first and second active layers AL4a and AL4b. For details of other elements, reference is made to the first embodiment. In some embodiments, the middle region MR4 may be disposed between the channel region CH4a and the channel region CH4b adjacent to each other among the plurality of channel regions CH4a, CH4b, the channel region CH4a may be disposed in the first active layer AL4a, and the channel region AL4b may be disposed in the second active layer AL4b. The channel region CH4a may be between the second region S4 and the first portion MR4a of the middle region MR4, and the channel region CH4b may be between the first lightly doped region LDD4 and the second portion MR4b of the middle region MR4. In some embodiments, the first portion MR4a and the second portion MR4b may be spaced apart from each other. The descriptions for other components shown in FIG. 3 (e.g., the gates TG4) may be referred to the same of similar terms or reference numerals used in the foregoing embodiments and are not repeated herein for brevity.

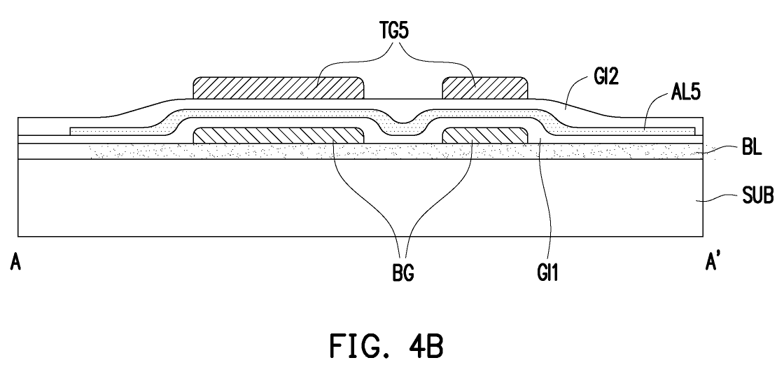

In the fifth embodiment, as shown in FIG. 4A and FIG. 4B, the transistor TR5 may have channel regions, and the channel lengths of at least two of the channel regions (e.g., channel regions CH5a and CH5b) may be different. In this embodiment, the length of the channel region CH5a in the X direction may be greater than the length of channel region CH5b in the X direction, but is not limited thereto. In some embodiments, as shown in FIG. 4A, the channel width of the at least two of the channel regions (e.g., channel regions CH5a and CH5b) may be the same. For example, the width of the channel region CH5a in the Y direction may be the same as the width of the channel region CH5b in the Y direction, but is not limited thereto. The descriptions for other components shown in FIG. 4A (e.g., the gates TG5, the middle region MR5, and the first lightly doped region LDD5) may be referred to the same of similar terms or reference numerals used in the foregoing embodiments and are not repeated herein for brevity.

In some embodiments, as shown in FIG. 4B, the transistor TR5 may be a dual-gate thin film transistor. In this embodiment, the transistor TR5 may further include a plurality of gates BG, a gate insulation layer GI1 disposed between the plurality of gates BG and the semiconductor AL5, and a gate insulation layer GI2 disposed between the plurality of gates TG5 and the semiconductor AL5. In this embodiment, the gates BG may be the bottom gates of the dual-gate thin film transistor, while the gates TG5 may be the top gates of the dual-gate thin film transistor. The gates BG may be disposed above the substrate SUB. The materials for these layers can be understood by reference to the foregoing embodiments. In some embodiments, the gates BG may be disposed on a buffer layer BL formed on the substrate SUB. The buffer layer BL may include any suitable dielectric material such as oxides, nitrides or combinations thereof.

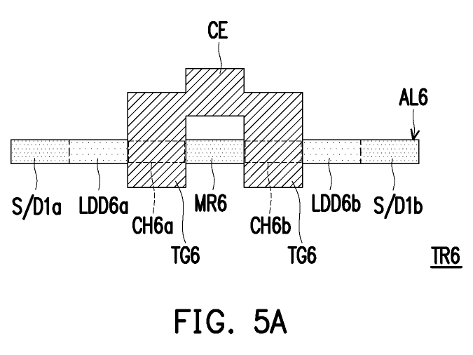

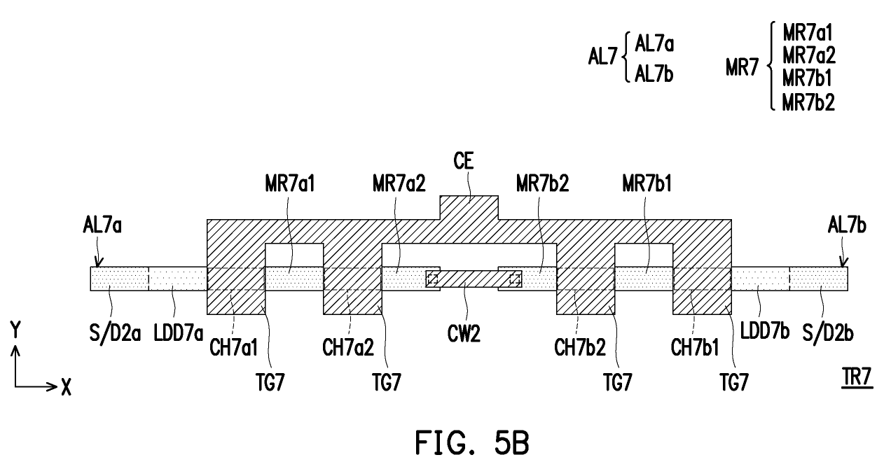

In the sixth embodiment, as shown in FIG. 5A, the transistor TR6 may be applicable in the embodiments where the source and the drain may be exchanged (e.g., a transistor in the active region of the display panel for controlling a pixel voltage). The semiconductor AL6 of the transistor TR6 may include a first lightly doped region LDD6a disposed between the first region S/D1a and the channel region CH6a among the channel regions CH6a, CH6b adjacent to the first region S/D1a, and a second lightly doped region LDD6b disposed between the second region S/D1b and the channel region CH6b among the plurality of channel regions CH6a, CH6b adjacent to the second region S/D1b. In this embodiment, the first lightly doped region LDD6a and the second lightly doped region LDD6b of the transistor TR6 may be formed in the semiconductor AL6 in a symmetric manner. In this embodiment, the middle region MR6 of the transistor TR6 may be between and directly adjacent to the two neighboring channel regions CH6a, CH6b. For example, no lightly doped region is formed in the portion of the middle region MR6 adjacent to the channel regions CH6a, CH6b. In some embodiments, in the case where no lightly doped region is formed in the portion of the middle region MR6 adjacent to the channel regions CH6a, CH6b, for the first and second concentrations at any two points in the middle region MR6, the ratio of the second concentration to the first concentration is less than or equal to 2 as the second concentration is greater than the first concentration. In some embodiments, an ion concentration doped in the at least one middle region MR6 may be greater than an ion concentration doped in the second lightly doped region LDD6b. In some embodiments, a ratio of the ion concentration doped in the at least one middle region MR6 to the ion concentration doped in the second lightly doped region LDD6b is greater than or equal to 2. In some other embodiments, the transistor TR6 may also include more than two channel regions, such as the transistor TR3 including three channel regions CH3a, CH3b, CH3c as shown in FIG. 2C or a transistor including four channel regions (not shown). The descriptions for other components shown in FIG. 5A (e.g., the gates TG6) may be referred to the same of similar terms or reference numerals used in the foregoing embodiments and are not repeated herein for brevity.

In the seventh embodiment, as shown in FIG. 5B, the transistor TR7 may be applicable in embodiments where the source and drain are exchanged (e.g., a transistor in the active region of the display panel for controlling a pixel voltage). The transistor TR7 may include a semiconductor AL7 including a first active layer AL7a and a second active layer AL7b spaced apart from the first active layer AL7a. The first active layer AL7a may include the first region S/D2a, the first lightly doped region LDD7a, the channel regions CH7a1, CH7a2, and the first portion MR7a1 and second portion MR7a2 of the middle region MR7. The second active layer AL7b may include the second region S/D2b, the second lightly doped region LDD7b, the channel regions CH7b1, CH7b2, and the first portion MR7b1 and second portion MR7b2 of the middle region MR7. In some embodiments, the first portion MR7a1 may be disposed between the two neighboring channel region CH7a1 and the channel region CH7a2, and the first portion MR7b1 may be disposed between the two neighboring channel region CH7b1 and the channel region CH7b2. In some embodiments, the plurality of second portions MR7a2, MR7b2 may be respectively disposed in the first active layer AL7a and the second active layer AL7b, the channel region CH7a2 may be disposed between the first portion MR7a1 and the second portion MR7a2, and the channel region CH7b2 may be disposed between the first portion MR7b1 and the second portion MR7b2.

In some embodiments, as shown in FIG. 5B, at least two of the channel regions CH7a1, CH7a2, CH7b1, CH7b2 may have the same channel length. The channel length may refer to the length of the channel in the direction from the source to the drain. For example, the lengths of the channel regions CH7a1, CH7a2, CH7b1, CH7b2 in the X direction may be identical to each other, but are not limited thereto. In some other embodiments, at least two of the plurality of channel regions CH7a1, CH7a2, CH7b1, CH7b2 may have different channel lengths.

In some embodiments, the transistor TR7 may further include a conductor CW2 electrically connecting the second portion MR7a2 and the second portion MR7b2 of the middle region MR7. In this embodiment, the conductor CW2 may electrically connect the first active layer AL7a to the second active layer AL7b. In this embodiment, the conductor CW2 may electrically connect two neighboring channel regions CH7a2, CH7b2 among the plurality of channel regions CH7a1, CH7a2, CH7b1, CH7b2. For example, the channel regions CH7a1, CH7a2 in the first active layer AL7a may be connected to the channel regions CH7b1, CH7b2 in the second active layer AL7b through the conductor CW2, to electrically connect the channel regions CH7a1, CH7a2 in the first active layer AL7a to the channel regions CH7b1, CH7b2 in the second active layer AL7b. In some embodiments, the conductor CW2 may be formed simultaneously with the gates TG7 in the same process, but is not limited thereto. In some other embodiments, the conductor CW2 and the gates TG7 may be formed in a different process. For example, the conductor CW2 may be one or more of the plurality of wiring layers formed above the gates TG7, but is not limited thereto. The materials for these layers can be understood by reference to the foregoing embodiments.

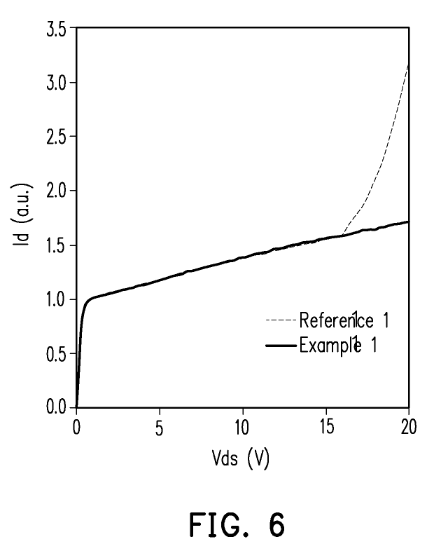

FIG. 6 is a schematic view showing a relationship of the current and the voltage of a transistor according to an embodiment of the present disclosure.

FIG. 6 shows a relationship of the drain-source voltage (Vds) and the drain current (Id) of the transistor, where the drain current (Id) is expressed in an arbitrary unit (a.u.) after normalization. Embodiment 1 shown in FIG. 6 may be, for example, the Vds versus Id curve of the transistor TR1 of the first embodiment. Reference example 1 shown in FIG. 6 may be, for example, the Vds versus Id curve of the transistor TR1 of the first embodiment in the case where the first lightly doped region LDD1 is not included. From FIG. 6, it can be seen that the transistor TR1 can reduce the phenomenon of generating kink current at the desired operating voltage.

In summary, in the transistor of the embodiment of the present disclosure, by disposing the first lightly doped region between the first region (e.g., drain region) and one of the plurality of channel regions, the electric field at the drain end may be reduced, and thereby improving the influence caused by the hot carrier effect, reducing the phenomenon of generating kink current at the desired operating voltage and/or decreasing the leakage current generated in the non-operating state.

The above embodiments are used to describe the technical solution of the disclosure and are not a limitation thereof. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

Although the embodiments of the disclosure and their advantages are disclosed as above, it should be understood that any person with ordinary skill in the art, without departing from the spirit and scope of the disclosure, may make changes, substitutions, and modifications, and features between the embodiments may be mixed and replaced at will to form other new embodiments. In addition, the scope of the disclosure is not limited to the manufacturing processes, machines, manufactures, material compositions, devices, methods, and steps in the specific embodiments described in the specification. Any person with ordinary skill in the art may understand the current or future development processes, machines, manufactures, material compositions, devices, methods, and steps from the content of the disclosure, which may all be adopted according to the disclosure as long as they may implement substantially the same function or obtain substantially the same result in an embodiment described here. Therefore, the scope of the disclosure includes the above manufacturing processes, machines, manufactures, material compositions, devices, methods, and steps. In addition, each claim constitutes an individual embodiment, and the scope of the disclosure also includes the combination of each claim and embodiment. The scope of the disclosure shall be subject to the scope defined by the following claims.

What is claimed is:

1. A transistor, comprising:
a semiconductor comprising:
a plurality of channel regions;
at least one middle region, wherein one of the at least one middle region is disposed between neighboring two of the plurality of channel regions;
a first region and a second region, respectively located at opposite ends of the semiconductor; and
a first lightly doped region, disposed between the first region and one of the plurality of channel regions adjacent to the first region; and
a plurality of gates, overlapping with the semiconductor, wherein each of the plurality of channel regions overlaps with one of the plurality of gates.

2. The transistor according to claim 1, wherein the first region is a drain region.

3. The transistor according to claim 1, wherein at least two of the plurality of channel regions have the same channel length.

4. The transistor according to claim 1, wherein at least two of the plurality of channel regions have different channel lengths.

5. The transistor according to claim 1, wherein at least two of the plurality of channel regions have different channel widths.

6. The transistor according to claim 1, further comprising:
a conductor, electrically connected to the at least one middle region.

7. The transistor according to claim 1, wherein an ion concentration doped in the at least one middle region is greater than an ion concentration doped in the first lightly doped region.

8. The transistor according to claim 7, wherein a ratio of the ion concentration doped in the at least one middle region to the ion concentration doped in the first lightly doped region is greater than or equal to 2.

9. The transistor according to claim 1, further comprising:
a second lightly doped region, disposed between the second region and one of the plurality of channel regions adjacent to the second region.

10. The transistor according to claim 9, wherein an ion concentration doped in the at least one middle region is greater than an ion concentration doped in the second lightly doped region.

11. The transistor according to claim 10, wherein a ratio of the ion concentration doped in the at least one middle region to the ion concentration doped in the second lightly doped region is greater than or equal to 2.

12. The transistor according to claim 1, wherein the at least one middle region comprises a first portion and a second portion, wherein a width of the first portion is different from a width of the second portion.

13. The transistor according to claim 1, wherein ions doped in the at least one middle region comprises a first concentration and a second concentration greater than the first concentration, and a ratio of the second concentration to the first concentration is less than or equal to 2.

14. The transistor according to claim 13, wherein one of the first concentration and the second concentration is a concentration at a location among the at least one middle region adjacent to one of the plurality of channel regions.

15. The transistor according to claim 1, wherein:
the semiconductor comprises a first active layer and a second active layer spaced apart from the first active layer, the at least one middle region is disposed between a first channel region and a second channel region adjacent to each other among the plurality of channel regions, the first channel region is disposed in the first active layer, and the second channel region is disposed in the second active layer;
the at least one middle region comprises a first portion disposed in the first active layer, and the first channel region is between the second region and the first portion; and
the at least one middle region comprises a second portion disposed in the second active layer, and the second channel region is between the first lightly doped region and the second portion.

16. The transistor according to claim 15, wherein the first portion of the at least one middle region and the second portion of the at least one middle region are spaced apart from each other.

17. The transistor according to claim 16, further comprising:
a conductor, electrically connecting the first portion of the at least one middle region to the second portion of the at least one middle region.

18. The transistor according to claim 1, wherein:
the semiconductor comprises a first active layer and a second active layer spaced apart from the first active layer, and the at least one middle region comprises a plurality of first portions and a plurality of second portions;
the plurality of first portions are respectively disposed in the first active layer and the second active layer and are respectively disposed between a first channel region and a second channel region that are adjacent to each other in the first active layer among the plurality of channel regions and between a third channel region and a fourth channel region that are adjacent to each other in the second active layer among the plurality of channel regions;
the plurality of second portions are respectively disposed in the first active layer and the second active layer, and one of the first channel region and the second channel region is disposed between the first portion and the second portion, and one of the third channel region and the fourth channel region is disposed between the first portion and the second portion.

19. The transistor according to claim 18, further comprising a conductor electrically connecting the plurality of second portions of the at least one middle region.

20. The transistor according to claim 1, wherein the plurality of gates comprises first gates disposed above the semiconductor and second gates disposed below the semiconductor.
